(19) United States
(12) Patent Application Publication
(10) Pub. No.: US 2026/0293784 A1
(43) Pub. Date: Sep. 24, 2026

(54) SEMICONDUCTOR DIE AND SEMICONDUCTOR PACKAGE INCLUDING THE SEMICONDUCTOR DIE

(71) Applicant: SK hynix Inc., Icheon-si Gyeonggi-do (KR)

(72) Inventor: Seong Ju LEE, San Jose, CA (US)

(73) Assignee: SK hynix Inc., Icheon-si Gyeonggi-do (KR)

(21) Appl. No.: 19/537,713

(22) Filed: Feb. 12, 2026

Related U.S. Application Data
(60) Provisional application No. 63/775,153, filed on Mar. 20, 2025.

(30) Foreign Application Priority Data
Aug. 27, 2025 (KR) 10-2025-0120332

(51) Int. Cl. H10W 90/00

(52) U.S. Cl. CPC H10W 90/724

(57) ABSTRACT

A semiconductor package includes a package substrate, a first semiconductor die, and a second semiconductor die. First data pads of the first semiconductor die and second data pads of the second semiconductor die are coupled in common to substrate data pads of the package substrate. The first semiconductor die electrically couples a data input/output circuit block of the first semiconductor die to the first data pads based on a first enable signal. The second semiconductor die electrically couples a data input/output circuit block of the second semiconductor die to the second data pads based on a second enable signal.

### CROSS-REFERENCES TO RELATED APPLICATION

The present application claims benefit under 35 U.S.C. § 119(e) of U.S. Provisional application number 63/775,153 filed on Mar. 20, 2025, and claims priority under 35 U.S.C. § 119(a) to Korean application number 10-2025-0120332 filed on Aug. 27, 2025, in the Korean Intellectual Property Office, the entire contents of which applications are incorporated herein by reference.

### BACKGROUND

### 1. Technical Field

Various embodiments generally relate to a method for designing an integrated circuit, and, more particularly, to a semiconductor die and a semiconductor package including the semiconductor die.

### 2. Related Art

Recently, with the emergence of big data, artificial intelligence, and high-performance applications, the amount of data processed in computing systems has increased and computing performance has become more advanced. In general, a computing system may include a host apparatus and a memory apparatus. The host apparatus may access the memory apparatus to read data for computation, perform computation on the read data, and write the computed data back to the memory apparatus. As the computing performance of the host apparatus increases, a greater amount of data needs to be transmitted between the host apparatus and the memory apparatus, and accordingly, the memory capacity and data bandwidth of the memory apparatus must expand to support the higher performance requirements.

To increase the memory capacity, a stacked semiconductor package structure with multiple memory dies arranged in a vertical stack and two or more memory dies connected in common to a data bus has been used. During a write operation, an external apparatus connected to the data bus must drive the combined loading of the two or more memory dies. During a read operation, a memory die performing the read operation must drive the loading presented by the remaining memory dies and the external apparatus. Due to these load conditions, achieving a data transfer speed that meets the target performance level becomes difficult.

### SUMMARY

In an embodiment, a semiconductor die includes a first data pad, a second data pad, a first data input/output circuit, a second data input/output circuit, a first switching circuit, and a second switching circuit. The first data pad may be coupled to a first data transmission line that transmits a first data signal. The second data pad may be coupled to a second data transmission line that transmits a second data signal. The first data input/output circuit may be configured to generate the first data signal based on a first internal data signal and may be configured to generate the first internal data signal based on the first data signal. The second data input/output circuit may be configured to generate the second data signal based on a second internal data signal and may be configured to generate the second internal data signal based on the second data signal. The first switching circuit may be configured to couple the first data pad and the first data input/output circuit based on an enable signal. The second switching circuit may be configured to couple the second data pad and the second data input/output circuit based on the enable signal.

In an embodiment, a semiconductor package includes a package substrate, a first semiconductor die, and a second semiconductor die. The package substrate may have substrate data pads coupled to a data bus that transmits data. The first semiconductor die may be disposed on the package substrate. The second semiconductor die may be disposed on the first semiconductor die. The first semiconductor die may include first data pads coupled to the substrate data pads, a first data input/output circuit block that may be configured to generate first internal data based on the data and may be configured to generate the data based on the first internal data, and a first switching circuit block that may be configured to selectively couple the first data pads and the first data input/output circuit block based on a first chip selection signal. The second semiconductor die may include second data pads coupled to the substrate data pads, a second data input/output circuit block that may be configured to generate second internal data based on the data and may be configured to generate the data based on the second internal data, and a second switching circuit block that may be configured to selectively couple the second data pads and the second data input/output circuit block based on a second chip selection signal.

In an embodiment, a semiconductor package includes a package substrate, a first semiconductor die, and a second semiconductor die. The package substrate may include substrate data pads coupled to a data bus that transmits data. The first semiconductor die may be disposed on the package substrate. The second semiconductor die may be disposed on the first semiconductor die. The first data pads of the first semiconductor die and the second data pads of the second semiconductor die may be coupled in common with the substrate data pads. The first data pads may be selectively coupled to a data input/output circuit block of the first semiconductor die based on a first enable signal, and the second data pads may be selectively coupled to a data input/output circuit block of the second semiconductor die based on a second enable signal.

In an embodiment, a semiconductor package includes a package substrate, a first semiconductor die, a second semiconductor die, a third semiconductor die, and a fourth semiconductor die. The package substrate may include first substrate data pads coupled to a first data bus and second substrate data pads coupled to a second data bus. The first semiconductor die may be disposed on the package substrate. The second semiconductor die may be disposed on the first semiconductor die. The third semiconductor die may be disposed on the second semiconductor die. The fourth semiconductor die may be disposed on the third semiconductor die. The first data pads of the first semiconductor die and the second data pads of the second semiconductor die may be coupled in common with the first substrate data pads, and the third data pads of the third semiconductor die and the fourth data pads of the fourth semiconductor die may be coupled in common with the second substrate data pads. When a first chip selection signal is enabled, a data input/output circuit block of the first semiconductor die may be coupled to the first data pads, and a data input/output circuit block of the third semiconductor die may be coupled to the third data pads. When a second chip selection signal is enabled, a data input/output circuit block of the second semiconductor die may be coupled to the second data pads, and a data input/output circuit block of the fourth semiconductor die may be coupled to the fourth data pads.

### BRIEF DESCRIPTION OF THE DRAWINGS

FIG. 1 is a diagram illustrating a configuration of a semiconductor package according to an embodiment of the present disclosure.

FIG. 2 is a diagram illustrating a conceptual connection relationship between pads of a package substrate and pads of a plurality of semiconductor dies in a semiconductor package according to an embodiment of the present disclosure.

FIG. 3 is a diagram illustrating a configuration of a semiconductor die according to an embodiment of the present disclosure.

FIG. 4 is a diagram illustrating a configuration of a command address control circuit according to an embodiment of the present disclosure.

FIG. 5 is a timing diagram illustrating an operation of a semiconductor package according to an embodiment of the present disclosure.

FIG. 6 is a diagram illustrating a configuration of a semiconductor package according to an embodiment of the present disclosure.

### DETAILED DESCRIPTION

Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “row,” “column,” “inner,” “outer” and other terms implying relative spatial relationship or orientation are utilized for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

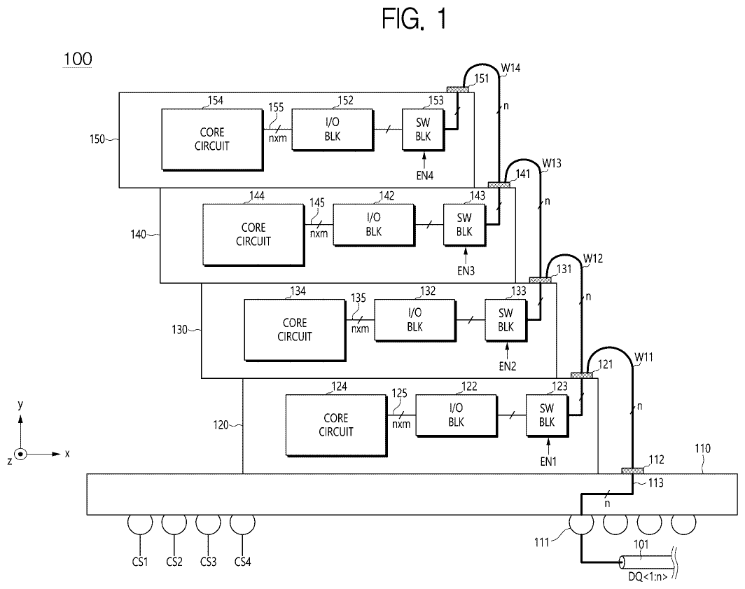

FIG. 1 is a diagram illustrating a configuration of a semiconductor package 100 according to an embodiment of the present disclosure. Referring to FIG. 1, the semiconductor package 100 may include a package substrate 110 and a plurality of dies. In FIG. 1, the semiconductor package 100 is illustrated as including a first semiconductor die 120, a second semiconductor die 130, a third semiconductor die 140, and a fourth semiconductor die 150, but it is not intended to limit the number of semiconductor dies included in the semiconductor package 100. The number of semiconductor dies included in the semiconductor package 100 may be less than four or greater than four.

The first to fourth semiconductor dies 120 to 150 may be disposed on the package substrate 110 and may be packaged into a single package. The first semiconductor die 120 may be disposed on the package substrate 110. For example, the first semiconductor die 120 may be disposed at a central portion of the package substrate 110 in x-axis and z-axis directions. The first semiconductor die 120 may be bonded to the package substrate 110 using an adhesive or a die attach film (DAF). The second semiconductor die 130 may be disposed on the first semiconductor die 120 in a y-axis direction. The third semiconductor die 140 may be disposed on the second semiconductor die 130 in the y-axis direction. The fourth semiconductor die 150 may be disposed on the third semiconductor die 140 in the y-axis direction. The second to fourth semiconductor dies 130-150 may be bonded to the first to third semiconductor dies 120 to 140, respectively, using a die attach film. The first to fourth semiconductor dies 120 to 150 may respectively include data pads on first sides thereof. Data pads of the first semiconductor die 120 may be referred to as first data pads 121. Data pads of the second semiconductor die 130 may be referred to as second data pads 131. Data pads of the third semiconductor die 140 may be referred to as third data pads 141. Data pads of the fourth semiconductor die 150 may be referred to as fourth data pads 151. The first to fourth semiconductor dies 120 to 150 may be sequentially arranged in a stepped shape such that the first to fourth data pads 121-151 are exposed. For example, the second semiconductor die 130 may be disposed on the first semiconductor die 120 while being shifted in a first direction of an x-axis (a left direction along the x-axis in FIG. 1). The third semiconductor die 140 may be disposed on the second semiconductor die 130 while being shifted from the second semiconductor die 130 in the first direction. The fourth semiconductor die 150 may be disposed on the third semiconductor die 140 while being shifted from the third semiconductor die 140 in the first direction.

The package substrate 110 may be coupled to an external apparatus through a data bus 101. The external apparatus may be a host apparatus capable of controlling various operations of the semiconductor package 100 and may include at least one of a central processing unit (CPU), a graphic processing unit (GPU), a neural processing unit (NPU), a multi-media processor (MMP), a digital signal processor (DSP), an application processor (AP), and a memory controller. The package substrate 110 may be coupled to the data bus 101 through a package ball 111. The package substrate 110 may include substrate data pads 112. The substrate data pads 112 may be coupled to the data bus 101. The substrate data pads 112 may be provided at positions spaced apart from the first semiconductor die 120 in a second direction opposite to the first direction. The number of the substrate data pads 112 may be substantially equal to the number of data transmission lines included in the data bus 101. The number of data signals included in data DQ<1:n> transmitted through the data bus 101 may be n, and the number of the substrate data pads 112 may be n. Here, n may be a multiple of four or a multiple of six. The substrate data pads 112 may be coupled to the data bus 101 through a signal path 113 formed in the package substrate 110 and the package ball 111. The first to fourth semiconductor dies 120 to 150 may share the data bus 101. The first data pads 121, the second data pads 131, the third data pads 141, and the fourth data pads 151 may be coupled in common to the substrate data pads 112. The first to fourth data pads 121-151 may each include n data pads. The first data pads 121 may be coupled to the substrate data pads 112 through first bonding wires W11. The second data pads 131 may be coupled to the first data pads 121 through second bonding wires W12. The third data pads 141 may be coupled to the second data pads 131 through third bonding wires W13. The fourth data pads 151 may be coupled to the third data pads 141 through fourth bonding wires W14. The number of the first to fourth bonding wires W11, W12, W13, and W14 may be n, respectively.

An internal circuit of the first semiconductor die 120 may be selectively coupled to the first data pads 121 based on a first enable signal EN1. An internal circuit of the second semiconductor die 130 may be selectively coupled to the second data pads 131 based on a second enable signal EN2. An internal circuit of the third semiconductor die 140 may be selectively coupled to the third data pads 141 based on a third enable signal EN3. An internal circuit of the fourth semiconductor die 150 may be selectively coupled to the fourth data pads 151 based on a fourth enable signal EN4. The first to fourth semiconductor dies 120 to 150 may be accessed based on different chip selection signals. The external apparatus may provide a first chip selection signal CS1, a second chip selection signal CS2, a third chip selection signal CS3, and a fourth chip selection signal CS4 to the semiconductor package 100. The package substrate 110 may receive the first to fourth chip selection signals CS1 to CS4 through the package ball 111, and the first to fourth chip selection signals CS1 to CS4 may be respectively provided to the first to fourth semiconductor dies 120 to 150. The first semiconductor die 120 may be accessed by the first chip selection signal CS1, and the first enable signal EN1 may be generated based on the first chip selection signal CS1. The second semiconductor die 130 may be accessed by the second chip selection signal CS2, and the second enable signal EN2 may be generated based on the second chip selection signal CS2. The third semiconductor die 140 may be accessed by the third chip selection signal CS3, and the third enable signal EN3 may be generated based on the third chip selection signal CS3. The fourth semiconductor die 150 may be accessed by the fourth chip selection signal CS4, and the fourth enable signal EN4 may be generated based on the fourth chip selection signal CS4. The internal circuits of the first to fourth semiconductor dies 120 to 150 may be respectively and selectively coupled to the first to fourth data pads 121 to 151 based on the first to fourth enable signals EN1 to EN4 or the first to fourth chip selection signals CS1 to CS4. The external apparatus may enable one of the first to fourth chip selection signals CS1 to CS4 to access one of the first to fourth semiconductor dies 120 to 150. For example, when the external apparatus accesses the first semiconductor die 120, the first chip selection signal CS1 may be enabled, and the first enable signal EN1 may be enabled based on the first chip selection signal CS1, while the second to fourth chip selection signals CS2 to CS4 and the second to fourth enable signals EN2 to EN4 may be disabled. Accordingly, the internal circuit of the first semiconductor die 120 may be coupled to the first data pads 121, while the internal circuits of the second to fourth semiconductor dies 130 to 150 may be electrically isolated from the second to fourth data pads 131 to 151. Although the data bus 101 is coupled in common to the first to fourth data pads 121 to 151, it may be coupled to loading of the internal circuit of the first semiconductor die 120 and might not be coupled to loadings of internal circuits of the second to fourth semiconductor dies 130 to 150. Because, in an embodiment, the external apparatus and/or the data bus 101 may be subjected to loading of only one semiconductor die at a time, a data transfer speed of the data bus 101 might not be reduced, and signal integrity (SI) of the data DQ<1:n> transmitted through the data bus 101 may be improved.

The first semiconductor die 120 may include the first data pads 121, a first data input/output circuit block I/O BLK 122, and a first switching circuit block SW BLK 123. The first data input/output circuit block 122 may be the internal circuit. The first data input/output circuit block 122 may generate first internal data 125 based on the data DQ<1:n> and may generate the data DQ<1:n> based on the first internal data 125. During a write operation of the first semiconductor die 120, the first data input/output circuit block 122 may receive, through the first data pads 121, the data DQ<1:n> transmitted from the external apparatus through the data bus 101 and may generate the first internal data 125 from the data DQ<1:n>. During a read operation of the first semiconductor die 120, the first data input/output circuit block 122 may generate the data DQ<1:n> based on the first internal data 125 and may output the data DQ<1:n> through the first data pads 121. The first data input/output circuit block 122 may include data receiving circuits for receiving the data DQ<1:n> and data transmitting circuits for outputting the data DQ<1:n>. The first data input/output circuit block 122 may further include a deserializer that deserializes the data DQ<1:n> to generate the first internal data 125 and a serializer that serializes the first internal data 125 to generate the data DQ<1:n>. The number of data signals included in the data DQ<1:n> may be n, and the number of internal data signals included in the first internal data 125 may be n×m. Here, m may be a burst length BL. The burst length may be the number of data words transmitted in one write operation or read operation. For example, when the burst length is 8, each of the n data signals included in the data DQ<1:n> may be an 8-bit serial data signal, and the first internal data 125 may include 8n internal data signals. The first data input/output circuit block 122 may include the number of data input/output circuits corresponding to the number of data transmission lines included in the data bus 101. For example, the first data input/output circuit block 122 may include n data input/output circuits respectively coupled to the n data transmission lines.

The first switching circuit block 123 may couple the first data pads 121 and the first data input/output circuit block 122. The first switching circuit block 123 may receive the first enable signal EN1 and may selectively couple the first data pads 121 and the first data input/output circuit block 122 based on the first enable signal EN1. When the first enable signal EN1 is enabled, the first switching circuit block 123 may couple the first data input/output circuit block 122 to the first data pads 121. When the first enable signal EN1 is disabled, the first switching circuit block 123 may electrically isolate the first data input/output circuit block 122 from the first data pads 121. The first switching circuit block 123 may couple data input/output circuits included in the first data input/output circuit block 122 to the first data pads 121 in a one-to-one manner. For example, the first switching circuit block 123 may include n switching circuits that respectively couple n data input/output circuits to n data pads.

The first semiconductor die 120 may further include a core circuit 124. The core circuit 124 may receive the first internal data 125, store the first internal data 125 in the core circuit 124, and output data stored in the core circuit 124 as the first internal data 125. The core circuit 124 may include a data storage region, a write circuit, and a read circuit. During the write operation, the write circuit may receive the first internal data 125 and store the first internal data 125 in the data storage region. During the read operation, the read circuit may read data stored in the data storage region and output the read data as the first internal data 125.

The second to fourth semiconductor dies 130-150 may include substantially the same configuration as the first semiconductor die 120. The second semiconductor die 130 may include the second data pads 131, a second data input/output circuit block I/O BLK 132, and a second switching circuit block SW BLK 133. The second data input/output circuit block 132 may generate second internal data 135 based on the data DQ<1:n> and may generate the data DQ<1:n> based on the second internal data 135. During a write operation of the second semiconductor die 130, the second data input/output circuit block 132 may receive the data DQ<1:n> transmitted from the external apparatus through the data bus 101 through the second data pads 131 and may generate the second internal data 135 from the data DQ<1:n>. During a read operation of the second semiconductor die 130, the second data input/output circuit block 132 may generate the data DQ<1:n> based on the second internal data 135 and may output the data DQ<1:n> through the second data pads 131. The second data input/output circuit block 132 may include data receiving circuits for receiving the data DQ<1:n> and data transmitting circuits for outputting the data DQ<1:n>. The second data input/output circuit block 132 may further include a deserializer that deserializes the data DQ<1:n> to generate the second internal data 135 and a serializer that serializes the second internal data 135 to generate the data DQ<1:n>. The number of internal data signals included in the second internal data 135 may be n×m. The second data input/output circuit block 132 may include n data input/output circuits respectively coupled to n data transmission lines.

The second switching circuit block 133 may couple the second data pads 131 and the second data input/output circuit block 132. The second switching circuit block 133 may receive the second enable signal EN2 and may selectively couple the second data pads 131 and the second data input/output circuit block 132 based on the second enable signal EN2. When the second enable signal EN2 is enabled, the second switching circuit block 133 may couple the second data input/output circuit block 132 to the second data pads 131. When the second enable signal EN2 is disabled, the second switching circuit block 133 may electrically isolate the second data input/output circuit block 132 from the second data pads 131. The second switching circuit block 133 may include n switching circuits respectively coupling n data input/output circuits to n data pads.

The second semiconductor die 130 may further include a core circuit 134. The core circuit 134 may receive the second internal data 135, store the second internal data 135 in the core circuit 134, and output data stored in the core circuit 134 as the second internal data 135. The core circuit 134 may include a data storage region, a write circuit, and a read circuit. During the write operation, the write circuit may receive the second internal data 135 and store the second internal data 135 in the data storage region. During the read operation, the read circuit may read data stored in the data storage region and output the read data as the second internal data 135.

The third semiconductor die 140 may include the third data pads 141, a third data input/output circuit block I/O BLK 142, and a third switching circuit block SW BLK 143. The third data input/output circuit block 142 may generate third internal data 145 based on the data DQ<1:n> and may generate the data DQ<1:n> based on the third internal data 145. During a write operation of the third semiconductor die 140, the third data input/output circuit block 142 may receive the data DQ<1:n> transmitted from the external apparatus through the data bus 101 through the third data pads 141 and may generate the third internal data 145 from the data DQ<1:n>. During a read operation of the third semiconductor die 140, the third data input/output circuit block 142 may generate the data DQ<1:n> based on the third internal data 145 and may output the data DQ<1:n> through the third data pads 141. The third data input/output circuit block 142 may include data receiving circuits for receiving the data DQ<1:n> and data transmitting circuits for outputting the data DQ<1:n>. The third data input/output circuit block 142 may further include a deserializer that deserializes the data DQ<1:n> to generate the third internal data 145 and a serializer that serializes the third internal data 145 to generate the data DQ<1:n>. The number of internal data signals included in the third internal data 145 may be n×m. The third data input/output circuit block 142 may include n data input/output circuits respectively coupled to n data transmission lines.

The third switching circuit block 143 may couple the third data pads 141 and the third data input/output circuit block 142. The third switching circuit block 143 may receive the third enable signal EN3 and may selectively couple the third data pads 141 and the third data input/output circuit block 142 based on the third enable signal EN3. When the third enable signal EN3 is enabled, the third switching circuit block 143 may couple the third data input/output circuit block 142 to the third data pads 141. When the third enable signal EN3 is disabled, the third switching circuit block 143 may electrically isolate the third data input/output circuit block 142 from the third data pads 141. The third switching circuit block 143 may include n switching circuits that respectively couple n data input/output circuits to n data pads.

The third semiconductor die 140 may further include a core circuit 144. The core circuit 144 may receive the third internal data 145, may store the third internal data 145 in the core circuit 144, and may output data stored in the core circuit 144 as the third internal data 145. The core circuit 144 may include a data storage region, a write circuit, and a read circuit. During the write operation, the write circuit may receive the third internal data 145 and may store the third internal data 145 in the data storage region. During the read operation, the read circuit may read data stored in the data storage region and may output the read data as the third internal data 145.

The fourth semiconductor die 150 may include the fourth data pads 151, a fourth data input/output circuit block I/O BLK 152, and a fourth switching circuit block SW BLK 153. The fourth data input/output circuit block 152 may generate fourth internal data 155 based on the data DQ<1:n> and may generate the data DQ<1:n> based on the fourth internal data 155. During a write operation of the fourth semiconductor die 150, the fourth data input/output circuit block 152 may receive the data DQ<1:n> transmitted from the external apparatus through the data bus 101 through the fourth data pads 151 and may generate the fourth internal data 155 from the data DQ<1:n>. During a read operation of the fourth semiconductor die 150, the fourth data input/output circuit block 152 may generate the data DQ<1:n> based on the fourth internal data 155 and may output the data DQ<1:n> through the fourth data pads 151. The fourth data input/output circuit block 152 may include data receiving circuits for receiving the data DQ<1:n> and data transmitting circuits for outputting the data DQ<1:n>. The fourth data input/output circuit block 152 may further include a deserializer that deserializes the data DQ<1:n> to generate the fourth internal data 155 and a serializer that serializes the fourth internal data 155 to generate the data DQ<1:n>. The number of internal data signals included in the fourth internal data 155 may be n×m. The fourth data input/output circuit block 152 may include n data input/output circuits respectively coupled to n data transmission lines.

The fourth switching circuit block 153 may couple the fourth data pads 151 and the fourth data input/output circuit block 152. The fourth switching circuit block 153 may receive the fourth enable signal EN4 and may selectively couple the fourth data pads 151 and the fourth data input/output circuit block 152 based on the fourth enable signal EN4. When the fourth enable signal EN4 is enabled, the fourth switching circuit block 153 may couple the fourth data input/output circuit block 152 to the fourth data pads 151. When the fourth enable signal EN4 is disabled, the fourth switching circuit block 153 may electrically isolate the fourth data input/output circuit block 152 from the fourth data pads 151. The fourth switching circuit block 153 may include n switching circuits respectively coupling n data input/output circuits to n data pads.

The fourth semiconductor die 150 may further include a core circuit 154. The core circuit 154 may receive the fourth internal data 155, store the fourth internal data 155 in the core circuit 154, and output data stored in the core circuit 154 as the fourth internal data 155. The core circuit 154 may include a data storage region, a write circuit, and a read circuit. During the write operation, the write circuit may receive the fourth internal data 155 and store the fourth internal data 155 in the data storage region. During the read operation, the read circuit may read data stored in the data storage region and output the read data as the fourth internal data 155.

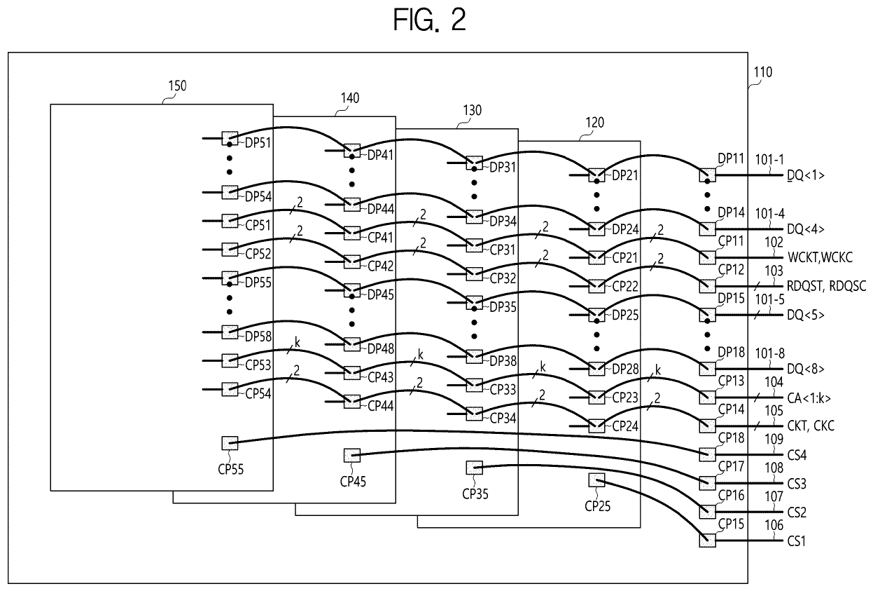

FIG. 2 is a diagram conceptually illustrating a connection relationship between pads of the package substrate 110 and pads of a plurality of semiconductor dies in the semiconductor package 100 according to an embodiment of the present disclosure. The number of pads illustrated in FIG. 2 is not limited but exemplary, and the numbers of pads included in the package substrate 110 and the first to fourth semiconductor dies 120 to 150 may variously change. Referring to FIG. 2, the package substrate 110 may include first to eighth data pads DP11 to DP18, a data clock pad CP11, a read strobe pad CP12, a command address pad CP13, a command clock pad CP14, a first chip selection pad CP15, a second chip selection pad CP16, a third chip selection pad CP17, and a fourth chip selection pad CP18. In an embodiment, the first to fourth data pads DP11 to DP14 may be disposed at one side (above the data clock pad CP11 and the read strobe pad CP12 in FIG. 2) of the data clock pad CP11 and the read strobe pad CP12, and the fifth to eighth data pads DP15 to DP18 may be disposed at the other side (below the data clock pad CP11 and the read strobe pad CP12 in FIG. 2) of the data clock pad CP11 and the read strobe pad CP12. The first to eighth data pads DP11 to DP18 may correspond to the substrate data pads 112 of FIG. 1. The first data pad DP11 may be coupled to a first data transmission line 101-1 of the data bus 101, and a first data signal DQ<1> may be transmitted through the first data transmission line 101-1. The fourth data pad DP14 may be coupled to a fourth data transmission line 101-4 of the data bus 101, and a fourth data signal DQ<4> may be transmitted through the fourth data transmission line 101-4. The fifth data pad DP15 may be coupled to a fifth data transmission line 101-5 of the data bus 101, and a fifth data signal DQ<5> may be transmitted through the fifth data transmission line 101-5. The eighth data pad DP18 may be coupled to an eighth data transmission line 101-8 of the data bus 101, and an eighth data signal DQ<8> may be transmitted through the eighth data transmission line 101-8. The data clock pad CP11 may be coupled to a data clock bus 102 and may receive a data clock signal WCKT and a complementary data clock signal WCKC through the data clock bus 102. The data clock bus 102 may include two data clock transmission lines respectively transmitting the data clock signal WCKT and the complementary data clock signal WCKC. The data clock pad CP11 may include two pads respectively coupled to the two data clock transmission lines and respectively receiving the data clock signal WCKT and the complementary data clock signal WCKC. The read strobe pad CP12 may be coupled to a read strobe bus 103 and a read strobe signal RDQST and a complementary read strobe signal RDQSC transmitted from the first to fourth semiconductor dies 120 to 150 may be transmitted to the external apparatus through the read strobe pad CP12. The read strobe bus 103 may include two read strobe transmission lines respectively transmitting the read strobe signal RDQST and the complementary read strobe signal RDQSC. The read strobe pad CP12 may include two pads respectively coupled to the two read strobe transmission lines and respectively outputting the read strobe signal RDQST and the complementary read strobe signal RDQSC. The command address pad CP13 may be coupled to a command address bus 104 and may receive a command address signal CA<1:k> through the command address bus 104. The command address signal CA<1:k> may include a plurality of bits, and the command address bus 104 may include a plurality of signal transmission lines respectively transmitting the plurality of bits. The command address pad CP13 may include a plurality of pads respectively coupled to the plurality of signal transmission lines and configured to receive respective bits of the command address signal CA<1:k>. The command clock pad CP14 may be coupled to a command clock bus 105 through which the external apparatus is coupled and may receive a command clock signal CKT and a complementary command clock signal CKC through the command clock bus 105. The command clock bus 105 may include two command clock transmission lines that respectively transmit the command clock signal CKT and the complementary command clock signal CKC. The command clock pad CP14 may include two pads respectively coupled to the two command clock transmission lines and configured to respectively receive the command clock signal CKT and the complementary command clock signal CKC. The first chip selection pad CP15 may be coupled to a first chip selection signal transmission line 106 and may receive the first chip selection signal CS1 through the first chip selection signal transmission line 106. The second chip selection pad CP16 may be coupled to a second chip selection signal transmission line 107 and may receive the second chip selection signal CS2 through the second chip selection signal transmission line 107. The third chip selection pad CP17 may be coupled to a third chip selection signal transmission line 108 and may receive the third chip selection signal CS3 through the third chip selection signal transmission line 108. The fourth chip selection pad CP18 may be coupled to a fourth chip selection signal transmission line 109 and may receive the fourth chip selection signal CS4 through the fourth chip selection signal transmission line 109.

The first semiconductor die 120 may include first to eighth data pads DP21 to DP28, a data clock pad CP21, a read strobe pad CP22, a command address pad CP23, a command clock pad CP24, and a chip selection pad CP25. The first to fourth data pads DP21 to DP24 may be disposed at one side (above the data clock pad CP21 and the read strobe pad CP22 in FIG. 2) of the data clock pad CP21 and the read strobe pad CP22, and the fifth to eighth data pads DP25 to DP28 may be disposed at the other side (below the data clock pad CP21 and the read strobe pad CP22 in FIG. 2) of the data clock pad CP21 and the read strobe pad CP22. The first to eighth data pads DP21 to DP28 may correspond to the first data pads 121 of FIG. 1. The first to fourth data pads DP21 to DP24 may be respectively coupled to the first to fourth data pads DP11 to DP14 of the package substrate 110 through bonding wires. The fifth to eighth data pads DP25 to DP28 may be respectively coupled to the fifth to eighth data pads DP15 to DP18 of the package substrate 110 through bonding wires. The data clock pad CP21 may be coupled to the data clock pad CP11 of the package substrate 110 through bonding wires. The read strobe pad CP22 may be coupled to the read strobe pad CP12 of the package substrate 110 through bonding wires. The command address pad CP23 may be coupled to the command address pad CP13 of the package substrate 110 through bonding wires. The command clock pad CP24 may be coupled to the command clock pad CP14 of the package substrate 110 through bonding wires. The chip selection pad CP25 may be coupled to the first chip selection pad CP15 of the package substrate 110 through a bonding wire.

The second semiconductor die 130 may include the first to eighth data pads DP31 to DP38, a data clock pad CP31, a read strobe pad CP32, a command address pad CP33, a command clock pad CP34, and a chip selection pad CP35. The first to fourth data pads DP31 to DP34 may be disposed at one side (above the data clock pad CP31 and the read strobe pad CP32 in FIG. 2) of the data clock pad CP31 and the read strobe pad CP32, and the fifth to eighth data pads DP35 to DP38 may be disposed at the other side (below the data clock pad CP31 and the read strobe pad CP32 in FIG. 2) of the data clock pad CP31 and the read strobe pad CP32. The first to eighth data pads DP31 to DP38 may correspond to the second data pads 131 of FIG. 1. The first to fourth data pads DP31 to DP34 may be respectively coupled to the first to fourth data pads DP21 to DP24 of the first semiconductor die 120 through bonding wires. The fifth to eighth data pads DP35 to DP38 may be respectively coupled to the fifth to eighth data pads DP25 to DP28 of the first semiconductor die 120 through bonding wires. The data clock pad CP31 may be coupled to the data clock pad CP21 of the first semiconductor die 120 through bonding wires. The read strobe pad CP32 may be coupled to the read strobe pad CP22 of the first semiconductor die 120 through bonding wires. The command address pad CP33 may be coupled to the command address pad CP23 of the first semiconductor die 120 through bonding wires. The command clock pad CP34 may be coupled to the command clock pad CP24 of the first semiconductor die 120 through bonding wires. The chip selection pad CP35 may be coupled to the second chip selection pad CP16 of the package substrate 110 through a bonding wire.

The third semiconductor die 140 may include first to eighth data pads DP41 to DP48, a data clock pad CP41, a read strobe pad CP42, a command address pad CP43, a command clock pad CP44, and a chip selection pad CP45. The first to fourth data pads DP41 to DP44 may be disposed at one side (above the data clock pad CP41 and the read strobe pad CP42 in FIG. 2) of the data clock pad CP41 and the read strobe pad CP42, and the fifth to eighth data pads DP45 to DP48 may be disposed at the other side (below the data clock pad CP41 and the read strobe pad CP42 in FIG. 2) of the data clock pad CP41 and the read strobe pad CP42. The first to eighth data pads DP41 to DP48 may correspond to the third data pads 141 of FIG. 1. The first to fourth data pads DP41 to DP44 may be respectively coupled to the first to fourth data pads DP31 to DP34 of the second semiconductor die 130 through bonding wires. The fifth to eighth data pads DP45 to DP48 may be respectively coupled to the fifth to eighth data pads DP35 to DP38 of the second semiconductor die 130 through bonding wires. The data clock pad CP41 may be coupled to the data clock pad CP31 of the second semiconductor die 130 through bonding wires. The read strobe pad CP42 may be coupled to the read strobe pad CP32 of the second semiconductor die 130 through bonding wires. The command address pad CP43 may be coupled to the command address pad CP33 of the second semiconductor die 130 through bonding wires. The command clock pad CP44 may be coupled to the command clock pad CP34 of the second semiconductor die 130 through bonding wires. The chip selection pad CP45 may be coupled to the third chip selection pad CP17 of the package substrate 110 through a bonding wire.

The fourth semiconductor die 150 may include first to eighth data pads DP51 to DP58, a data clock pad CP51, a read strobe pad CP52, a command address pad CP53, a command clock pad CP54, and a chip selection pad CP55. The first to fourth data pads DP51 to DP54 may be disposed at one side (above the data clock pad CP51 and the read strobe pad CP52 in FIG. 2) of the data clock pad CP51 and the read strobe pad CP52, and the fifth to eighth data pads DP55 to DP58 may be disposed at the other side (below the data clock pad CP51 and the read strobe pad CP52 in FIG. 2) of the data clock pad CP51 and the read strobe pad CP52. The first to eighth data pads DP51 to DP58 may correspond to the fourth data pads 151 of FIG. 1. The first to fourth data pads DP51 to DP54 may be respectively coupled to the first to fourth data pads DP41 to DP44 of the third semiconductor die 140 through bonding wires. The fifth to eighth data pads DP55 to DP58 may be respectively coupled to the fifth to eighth data pads DP45 to DP48 of the third semiconductor die 140 through bonding wires. The data clock pad CP51 may be coupled to the data clock pad CP41 of the third semiconductor die 140 through bonding wires. The read strobe pad CP52 may be coupled to the read strobe pad CP42 of the third semiconductor die 140 through bonding wires. The command address pad CP53 may be coupled to the command address pad CP43 of the third semiconductor die 140 through bonding wires. The command clock pad CP54 may be coupled to the command clock pad CP44 of the third semiconductor die 140 through bonding wires. The chip selection pad CP55 may be coupled to the fourth chip selection pad CP18 of the package substrate 110 through a bonding wire.

The first to fourth semiconductor dies 120 to 150 may have the first to eighth data pads DP21 to DP28, DP31 to DP38, DP41 to DP48, and DP51 to DP58 coupled in common to the first to eighth data pads DP11 to DP18 of the package substrate 110 and coupled in common to the data bus 101. The data clock pads CP21, CP31, CP41, and CP51 of the first to fourth semiconductor dies 120 to 150 may be coupled in common to the data clock pad CP11 of the package substrate 110 and may receive the data clock signal WCKT and the complementary data clock signal WCKC in common. The read strobe pads CP22, CP32, CP42, and CP52 of the first to fourth semiconductor dies 120 to 150 may be coupled in common to the read strobe pad CP12 of the package substrate 110 and may output the read strobe signal RDQST and the complementary read strobe signal RDQSC generated from the first to fourth semiconductor dies 120 to 150 in common. The command address pads CP23, CP33, CP43, and CP53 of the first to fourth semiconductor dies 120 to 150 may be coupled in common to the command address pad CP13 of the package substrate 110 and may commonly receive the command address signal CA<1:k> in common. The command clock pads CP24, CP34, CP44, and CP54 of the first to fourth semiconductor dies 120 to 150 may be coupled in common to the command clock pad CP14 of the package substrate 110 and may receive the command clock signal CKT and the complementary command clock signal CKC in common. The chip selection pads CP25, CP35, CP45, and CP55 of the first to fourth semiconductor dies 120 to 150 may be respectively coupled to the first to fourth chip selection pads CP15, CP16, CP17, and CP18 of the package substrate 110, and the first to fourth semiconductor dies 120 to 150 may receive different chip selection signals.

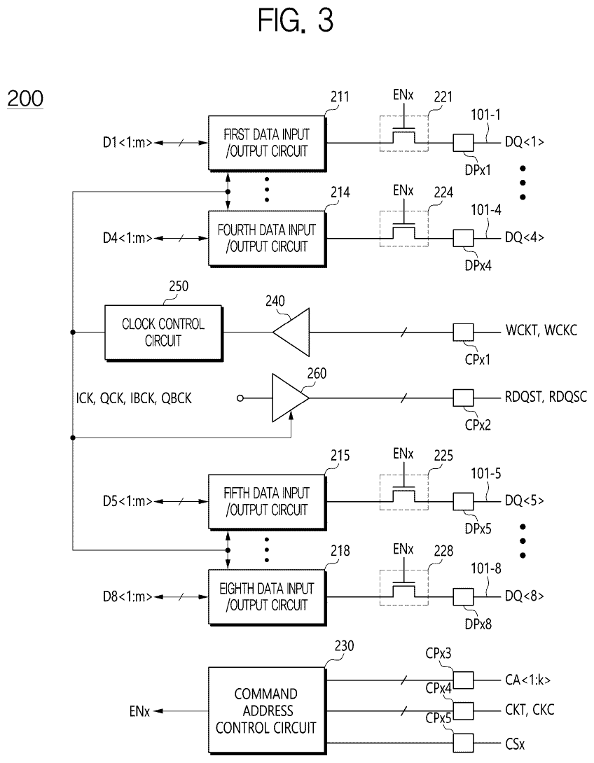

FIG. 3 is a diagram illustrating a configuration of a semiconductor die 200 according to an embodiment of the present disclosure. The first to fourth semiconductor dies 120 to 150 illustrated in FIGS. 1 and 2 may each be implemented as the semiconductor die 200. Referring to FIG. 3, the semiconductor die 200 may include first to eighth data input/output circuits 211 to 218 and first to eighth switching circuits 221 to 228. Each of the first to fourth data input/output circuit blocks 122, 132, 142, and 152 illustrated in FIG. 1 may include a plurality of data input/output circuits such as the first to eights data input/output circuits 211 to 218. Each of the first to fourth switching circuit blocks 123, 133, 143, and 153 illustrated in FIG. 1 may include a plurality of switching circuits such as the first to eights switching circuits 221 to 228. The first data input/output circuit 211 may be coupled to a first data pad DPx1 and may be coupled to a first data transmission line 101-1 transmitting a first data signal DQ<1>. The first data input/output circuit 211 may generate a first internal data signal D1<1:m> based on the first data signal DQ<1> and may generate the first data signal DQ<1> based on the first internal data signal D1<1:m>. The first data input/output circuit 211 may receive the first data signal DQ<1> during a write operation of the semiconductor die 200 and may generate the first internal data signal D1<1:m> from the first data signal DQ<1>. The first data input/output circuit 211 may generate the first data signal DQ<1> from the first internal data signal D1<1m> during a read operation of the semiconductor die 200 and may output the first data signal DQ<1> through the first data pad DPx1. The fourth data input/output circuit 214 may be coupled to a fourth data pad DPx4 and may be coupled to a fourth data transmission line 101-4 transmitting a fourth data signal DQ<4>. The fourth data input/output circuit 214 may generate a fourth internal data signal D4<1:m> based on the fourth data signal DQ<4> and may generate the fourth data signal DQ<4> based on the fourth internal data signal D4<1:m>. The fourth data input/output circuit 214 may receive the fourth data signal DQ<4> during a write operation of the semiconductor die 200 and may generate the fourth internal data signal D4<1:m> from the fourth data signal DQ<4>. The fourth data input/output circuit 214 may generate the fourth data signal DQ<4> from the fourth internal data signal D4<1:m> during a read operation of the semiconductor die 200 and may output the fourth data signal DQ<4> through the fourth data pad DPx4. The fifth data input/output circuit 215 may be coupled to a fifth data pad DPx5 and may be coupled to a fifth data transmission line 101-5 transmitting a fifth data signal DQ<5>. The fifth data input/output circuit 215 may generate a fifth internal data signal D5<1:m> based on the fifth data signal DQ<5> and may generate the fifth data signal DQ<5> based on the fifth internal data signal D5<1:m>. The fifth data input/output circuit 215 may receive the fifth data signal DQ<5> during a write operation of the semiconductor die 200 and may generate the fifth internal data signal D5<1:m> from the fifth data signal DQ<5>. The fifth data input/output circuit 215 may generate the fifth data signal DQ<5> from the fifth internal data signal D5<1:m> during a read operation of the semiconductor die 200 and may output the fifth data signal DQ<5> through the fifth data pad DPx5. The eighth data input/output circuit 218 may be coupled to an eighth data pad DPx8 and may be coupled to an eighth data transmission line 101-8 transmitting an eighth data signal DQ<8>. The eighth data input/output circuit 218 may generate an eighth internal data signal D8<1:m> based on the eighth data signal DQ<8> and may generate the eighth data signal DQ<8> based on the eighth internal data signal D8<1:m>. The eighth data input/output circuit 218 may receive the eighth data signal DQ<8> during a write operation of the semiconductor die 200 and may generate the eighth internal data signal D8<1m> from the eighth data signal DQ<8>. The eighth data input/output circuit 218 may generate the eighth data signal DQ<8> from the eighth internal data signal D8<1:m> during a read operation of the semiconductor die 200 and may output the eighth data signal DQ<8> through the eighth data pad DPx8.

The first switching circuit 221 may couple the first data input/output circuit 211 and the first data pad DPx1 based on an enable signal ENx. The first switching circuit 221 may selectively couple the first data input/output circuit 211 to the first data pad DPx1 according to whether the enable signal ENx is enabled. When the enable signal ENx is enabled, the first switching circuit 221 may electrically couple the first data input/output circuit 211 to the first data pad DPx1. When the enable signal ENx is disabled, the first switching circuit 221 may electrically isolate the first data input/output circuit 211 from the first data pad DPx1. The fourth switching circuit 224 may couple the fourth data input/output circuit 214 and the fourth data pad DPx4 based on the enable signal ENx. The fourth switching circuit 224 may selectively couple the fourth data input/output circuit 214 to the fourth data pad DPx4 according to whether the enable signal ENx is enabled. When the enable signal ENx is enabled, the fourth switching circuit 224 may electrically couple the fourth data input/output circuit 214 to the fourth data pad DPx4. When the enable signal ENx is disabled, the fourth switching circuit 224 may electrically isolate the fourth data input/output circuit 214 from the fourth data pad DPx4. The fifth switching circuit 225 may couple the fifth data input/output circuit 215 and the fifth data pad DPx5 based on the enable signal ENx. The fifth switching circuit 225 may selectively couple the fifth data input/output circuit 215 to the fifth data pad DPx5 according to whether the enable signal ENx is enabled. When the enable signal ENx is enabled, the fifth switching circuit 225 may electrically couple the fifth data input/output circuit 215 to the fifth data pad DPx5. When the enable signal ENx is disabled, the fifth switching circuit 225 may electrically isolate the fifth data input/output circuit 215 from the fifth data pad DPx5. The eighth switching circuit 228 may couple the eighth data input/output circuit 218 and the eighth data pad DPx8 based on the enable signal ENx. The eighth switching circuit 228 may selectively couple the eighth data input/output circuit 218 to the eighth data pad DPx8 according to whether the enable signal ENx is enabled. When the enable signal ENx is enabled, the eighth switching circuit 228 may electrically couple the eighth data input/output circuit 218 to the eighth data pad DPx8. When the enable signal ENx is disabled, the eighth switching circuit 228 may electrically isolate the eighth data input/output circuit 218 from the eighth data pad DPx8.

The semiconductor die 200 may further include a command address control circuit 230. The command address control circuit 230 may be coupled to a command address pad CPx3 and a chip selection pad CPx5 and may receive a command address signal CA<1:k> and a chip selection signal CSx. The command address control circuit 230 may generate the enable signal ENx based on the command address signal CA<1:k> and the chip selection signal CSx. When the chip selection signal CSx is enabled, the command address control circuit 230 may decode the command address signal CA<1:k> to generate internal command signals and may generate the enable signal ENx from the internal command signals. The command address control circuit 230 may enable the enable signal ENx when the chip selection signal CSx is enabled and the command address signal CA<1:k> includes one of a write command and a read command. The semiconductor die 200 may perform a write operation based on the command address signal CA<1:k> including the write command and may perform a read operation based on the command address signal CA<1:k> including the read command. During the write operation of the semiconductor die 200, the command address control circuit 230 may enable the enable signal ENx before the first to eighth data signals DQ<1> to DQ<8> are received through the first to eighth data pads DPx1 to DPx8, and may disable the enable signal ENx after reception of the first to eighth data signals DQ<1> to DQ<8> through the first to eighth data pads DPx1 to DPx8 is completed. During the read operation of the semiconductor die 200, the command address control circuit 230 may enable the enable signal ENx before the first to eighth data signals DQ<1> to DQ<8> are output from the first to eighth data input/output circuits 211 to 218, and may disable the enable signal ENx after output of the first to eighth data signals DQ<1> to DQ<8> from the first to eighth data input/output circuits 211 to 218 is completed. The command address control circuit 230 may be further coupled to a command clock pad CPx4 and may further receive a command clock signal CKT and a complementary command clock signal CKC through the command clock pad CPx4. The command address control circuit 230 may receive the command address signal CA<1:k> and the chip selection signal CSx in synchronization with the command clock signal CKT and the complementary command clock signal CKC. The command address control circuit 230 may use the command clock signal CKT and the complementary command clock signal CKC to generate the enable signal ENx from the internal command signals.

The semiconductor die 200 may further include a clock receiving circuit 240, a clock control circuit 250, and a strobe transmission circuit 260. The clock receiving circuit 240 may be coupled to a data clock pad CPx1 and may receive a data clock signal WCKT and a complementary data clock signal WCKC through the data clock pad CPx1. The clock receiving circuit 240 may differentially amplify the data clock signal WCKT and the complementary data clock signal WCKC. The clock control circuit 250 may receive the data clock signal WCKT and the complementary data clock signal WCKC from the clock receiving circuit 240 and may generate a plurality of internal clock signals based on the data clock signal WCKT and the complementary data clock signal WCKC. The plurality of internal clock signals may include a first internal clock signal ICK, a second internal clock signal QCK, a third internal clock signal IBCK, and a fourth internal clock signal QBCK. The first to fourth internal clock signals ICK, QCK, IBCK, and QBCK may sequentially have a phase difference of 90 degrees and may have lower frequencies than the data clock signal WCKT. For example, the clock control circuit 250 may generate the first to fourth internal clock signals ICK, QCK, IBCK, and QBCK by dividing the frequencies of the data clock signal WCKT and the complementary data clock signal WCKC. The strobe transmission circuit 260 may receive the first to fourth internal clock signals ICK, QCK, IBCK, and QBCK and may generate a read strobe signal RDQST and a complementary read strobe signal RDQSC based on the first to fourth internal clock signals. The strobe transmission circuit 260 may be coupled to the read strobe pad CPx2 and may output the read strobe signal RDQST and the complementary read strobe signal RDQSC through the read strobe pad CPx2. The first to eighth data input/output circuits 211 to 218 may receive the first to fourth internal clock signals ICK, QCK, IBCK, and QBCK in common. The first to eighth data input/output circuits 211 to 218 may perform data input/output operations in synchronization with the first to fourth internal clock signals ICK, QCK, IBCK, and QBCK. For example, during the write operation, the first to eighth data input/output circuits 211 to 218 may respectively receive the first to eighth data signals DQ<1> to DQ<8> in synchronization with the first to fourth internal clock signals ICK, QCK, IBCK, and QBCK, and may respectively generate the first to eighth internal data signals D1<1:m> to D8<1m> from the first to eighth data signals DQ<1> to DQ<8> in synchronization with the first to fourth internal clock signals ICK, QCK, IBCK, and QBCK. During the read operation, the first to eighth data input/output circuits 211 to 218 may respectively generate the first to eighth data signals DQ<1> to DQ<8> from the first to eighth internal data signals D1<1:m> to D8<1:m> in synchronization with the first to fourth internal clock signals ICK, QCK, IBCK, and QBCK, and may respectively output the first to eighth data signals DQ<1> to DQ<8> in synchronization with the first to fourth internal clock signals ICK, QCK, IBCK, and QBCK.

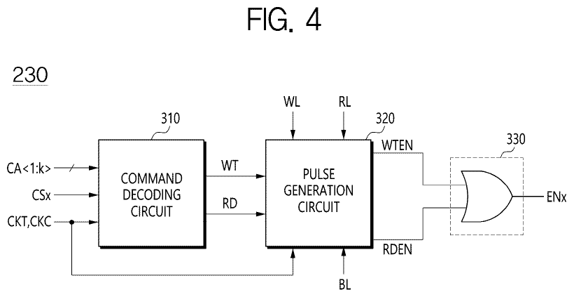

FIG. 4 is a diagram illustrating a configuration of the command address control circuit 230 according to an embodiment of the present disclosure. Referring to FIG. 4, the command address control circuit 230 may include a command decoding circuit 310, a pulse generation circuit 320, and an enable signal generation circuit 330. The command decoding circuit 310 may receive the command address signal CA<1:k>, the chip selection signal CSx, the command clock signal CKT, and the complementary command clock signal CKC. The command decoding circuit 310 may generate the internal command signals based on the command address signal CA<1:k> when the chip selection signal CSx is enabled. The internal command signals may include a write signal WT and a read signal RD. The command decoding circuit 310 might not receive the command address signal CA<1:k> when the chip selection signal CSx is disabled. The command decoding circuit 310 may receive the command address signal CA<1:k>b y comparing bits of the command address signal CA<1:k> with a reference voltage. The command decoding circuit 310 may latch the command address signal CA<1:k> in synchronization with the command clock signal CKT and the complementary command clock signal CKC. The command decoding circuit 310 may decode the latched command address signal to generate the write signal WT and the read signal RD. When the command address signal CA<1:k> includes the write command, the command decoding circuit 310 may decode the latched command address signal to generate the write signal WT. When the command address signal CA<1:k> includes the read command, the command decoding circuit 310 may decode the latched command address signal to generate the read signal RD.

The pulse generation circuit 320 may receive the write signal WT, the read signal RD, the command clock signal CKT, and the complementary command clock signal CKC. Also, the pulse generation circuit 320 may receive write latency information WL, read latency information RL, and burst length information BL. The write latency may be a delay time from a point in time when the semiconductor die 200 illustrated in FIG. 3 receives the command address signal CA<1:k> including the write command to a point in time when the semiconductor die 200 receives the data DQ<1:8> through the data bus 101. The read latency may be a delay time from a point in time when the semiconductor die 200 receives the command address signal CA<1:k> including the read command to a point in time when the semiconductor die 200 outputs the data DQ<1:8> through the data bus 101. The pulse generation circuit 320 may generate a write enable signal WTEN from the write signal WT based on the write latency information WL and the burst length information BL and may generate a read enable signal RDEN from the read signal RD based on the read latency information RL and the burst length information BL. The pulse generation circuit 320 may generate the write enable signal WTEN having a pulse width that covers an interval in which the data DQ<1:8> is transmitted through the data bus 101 during the write operation. The pulse generation circuit 320 may generate the write enable signal WTEN having a pulse width that is enabled before a time corresponding to the write latency information WL elapses from the write signal WT and remains enabled for a time longer than a time corresponding to the burst length information BL. The pulse generation circuit 320 may generate the write enable signal WTEN by delaying the write signal WT according to the write latency information WL and the burst length information BL in synchronization with the command clock signal CKT and the complementary command clock signal CKC. The pulse generation circuit 320 may generate the read enable signal RDEN having a pulse width that covers an interval in which the data DQ<1:8> is transmitted through the data bus 101 during the read operation. The pulse generation circuit 320 may generate the read enable signal RDEN having a pulse width that is enabled before a time corresponding to the read latency information RL elapses from the read signal RD and remains enabled for a time longer than a time corresponding to the burst length information BL. The pulse generation circuit 320 may generate the read enable signal RDEN by delaying the read signal RD according to the read latency information RL and the burst length information BL in synchronization with the command clock signal CKT and the complementary command clock signal CKC. For example, when the read latency information RL is 10, the burst length information BL is 16, and the frequency ratio of the command clock signal CKT and the data clock signal WCKT is 1:4, the pulse generation circuit 320 may enable the read enable signal RDEN at a time before 10 tCK from the read signal RD and remains the enabled for a time longer than 4 tCK. The “tCK” may refer to a time corresponding to one period and/or cycle of the command clock signal CKT. In an embodiment, the frequency ratio of the command clock signal CKT and the data clock signal WCKT may be changed to 1:2, 1:8, etc. according to applications

The enable signal generation circuit 330 may receive the write enable signal WTEN and the read enable signal RDEN and may generate the enable signal ENx based on the write enable signal WTEN and the read enable signal RDEN. The enable signal generation circuit 330 may enable the enable signal ENx when any one of the write enable signal WTEN and the read enable signal RDEN is enabled. In an embodiment, the enable signal generation circuit 330 may include an OR gate configured to receive the write enable signal WTEN and the read enable signal RDEN and to output the enable signal ENx.

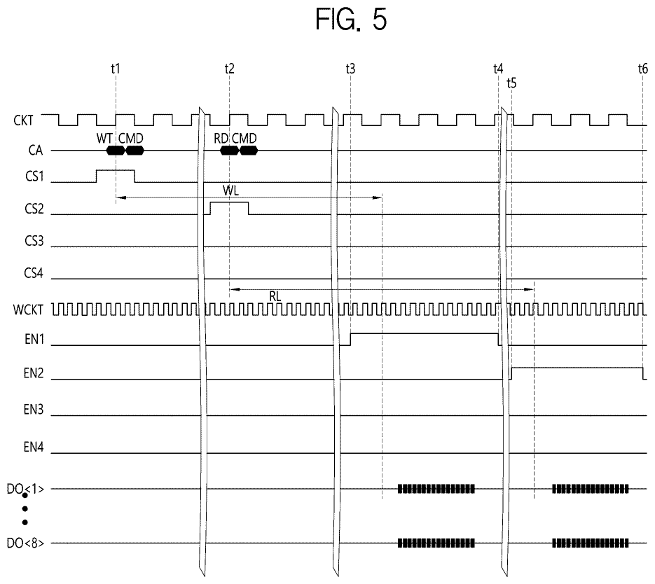

FIG. 5 is a diagram illustrating an operation of the semiconductor package 100 according to an embodiment of the present disclosure. Referring to FIGS. 1 to 5, an operation of the semiconductor package 100 according to an embodiment of the present disclosure will be described below. Before a first time t1, when no command address signal is transmitted from the external apparatus to the semiconductor package 100, the first to fourth enable signals EN1, EN2, EN3, and EN4 may all be maintained in a disabled state. The first to fourth switching circuit blocks 123, 133, 143, and 153 may electrically isolate the first to fourth data input/output circuit blocks 122, 132, 142, and 152 from the first to fourth data pads 121, 131, 141, and 151, respectively. At the first time t1, the external apparatus may provide to the semiconductor package 100 the command address signal CA<1:k> including the first chip selection signal CS1 and the write command WT CMD in synchronization with the command clock signal CKT. The first chip selection signal CS1 may be enabled, and the second to fourth chip selection signals CS2, CS3, and CS4 may all be disabled. The first semiconductor die 120 may perform a write operation based on the first chip selection signal CS1 and the command address signal CA<1:k>. At a second time t2, the external apparatus may provide to the semiconductor package 100 the command address signal CA<1:k> including the second chip selection signal CS2 and the read command RD CMD in synchronization with the command clock signal CKT. The second chip selection signal CS2 may be enabled, and first, third, and fourth chip selection signals CS1, CS3, and CS4 may all be disabled. The second semiconductor die 130 may perform a read operation based on the second chip selection signal CS2 and the command address signal CA<1:k>. t3 may be a time before a duration corresponding to the write latency information WL elapses from a time point when the first semiconductor die 120 receives the command address signal CA<1:k> including the write command WT CMD. At a third time t3, the command address control circuit 230 provided in the first semiconductor die 120 may enable the first enable signal EN1. When the first enable signal EN1 is enabled, the first switching circuit block 123 may couple the first data input/output circuit block 122 to the first data pads 121. The second to fourth data input/output circuit blocks 132, 142, and 152 may still be electrically isolated from the second to fourth data pads 131, 141, and 151, so that the external apparatus and the data bus 101 may be subject to only a loading corresponding to the first data input/output circuit block 122. When a duration corresponding to the write latency information WL elapses, the external apparatus may transmit the data DQ<1:n> through the data bus 101 in synchronization with the data clock signal WCKT. The data DQ<1:n> may be transmitted to the semiconductor package 100 for a duration corresponding to the burst length information BL. After the semiconductor package 100 completes reception of the data DQ<1:n>, at a fourth time t4, the first enable signal EN1 may be disabled, and the first switching circuit block 123 may electrically isolate the first data input/output circuit block 122 from the first data pads 121. t5 may be before a duration corresponding to the read latency information RL elapses from a time point when the second semiconductor die 130 receives the command address signal CA<1:k> including the read command RD CMD. At a fifth time t5, the command address control circuit 230 provided in the second semiconductor die 130 may enable the second enable signal EN2. When the second enable signal EN2 is enabled, the second switching circuit block 133 may couple the second data input/output circuit block 132 to the second data pads 131. Because the first, third, and fourth data input/output circuit blocks 122, 142, and 152 are electrically isolated from the first, third, and fourth data pads 121, 141, and 151, respectively, the external apparatus and the data bus 101 may be subject to only loading corresponding to the second data input/output circuit block 132. When a duration corresponding to the read latency information RL elapses, the second semiconductor die 130 may transmit the data DQ<1:n> to the external apparatus through the data bus 101 in synchronization with the data clock signal WCKT. The data DQ<1:n> may be output from the semiconductor package 100 for a duration corresponding to the burst length information BL. After the semiconductor package 100 completes transmission of the data DQ<1:n>, at a sixth time t6, the second enable signal EN2 may be disabled, and the second switching circuit block 133 may electrically isolate the second data input/output circuit block 132 from the second data pads 131. In an embodiment, the semiconductor package 100 may include a plurality of semiconductor dies coupled in common to the data bus 101 to increase a capacity of the semiconductor package 100, while only one semiconductor die performing the write operation or the read operation is coupled to the data bus 101, thereby reducing loading of the data bus 101 and mitigating and/or preventing a decrease in data transfer speed.

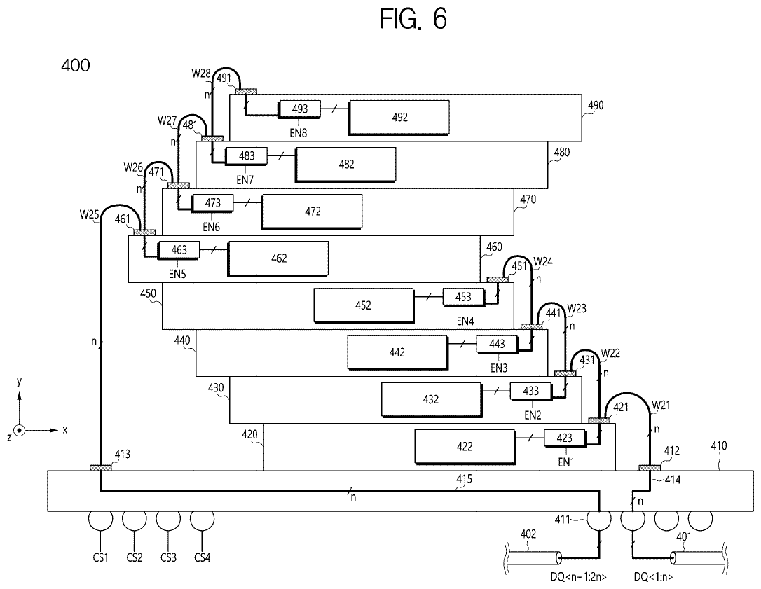

FIG. 6 is a diagram illustrating a configuration of a semiconductor package 400 according to an embodiment of the present disclosure. Referring to FIG. 6, the semiconductor package 400 may include a package substrate 410 and a plurality of dies. In FIG. 6, the semiconductor package 400 may include a first semiconductor die 420, a second semiconductor die 430, a third semiconductor die 440, a fourth semiconductor die 450, a fifth semiconductor die 460, a sixth semiconductor die 470, a seventh semiconductor die 480, and an eighth semiconductor die 490. Although the semiconductor package 400 is illustrated as including eight semiconductor dies in FIG. 6, it is not intended to limit the number of semiconductor dies included in the semiconductor package 400. The semiconductor package 400 may include twelve, sixteen, or more semiconductor dies. The first to eighth semiconductor dies 420 to 490 may be disposed on the package substrate 410 and may be packaged into a single package. The first semiconductor die 420 may be disposed on the package substrate 410. For example, the first semiconductor die 420 may be disposed at a central portion of the package substrate 410 in x-axis and z-axis directions. The first semiconductor die 420 may be bonded to the package substrate 410 using an adhesive or a die attach film (DAF). The second semiconductor die 430 may be disposed on the first semiconductor die 420 in a y-axis direction. The third semiconductor die 440 may be disposed on the second semiconductor die 430 in the y-axis direction. The fourth semiconductor die 450 may be disposed on the third semiconductor die 440 in the y-axis direction. The fifth semiconductor die 460 may be disposed on the fourth semiconductor die 450 in the y-axis direction. The sixth semiconductor die 470 may be disposed on the fifth semiconductor die 460 in the y-axis direction. The seventh semiconductor die 480 may be disposed on the sixth semiconductor die 470 in the y-axis direction. The eighth semiconductor die 490 may be disposed on the seventh semiconductor die 480 in the y-axis direction. The second to eighth semiconductor dies 430 to 490 may be bonded to the first to seventh semiconductor dies 420 to 480, respectively, using a die attach film. The first to eighth semiconductor dies 420 to 490 may respectively include data pads on first sides thereof. Data pads of the first semiconductor die 420 may be referred to as first data pads 421. Data pads of the second semiconductor die 430 may be referred to as second data pads 431. Data pads of the third semiconductor die 440 may be referred to as third data pads 441. Data pads of the fourth semiconductor die 450 may be referred to as fourth data pads 451. Data pads of the fifth semiconductor die 460 may be referred to as fifth data pads 461. Data pads of the sixth semiconductor die 470 may be referred to as sixth data pads 471. Data pads of the seventh semiconductor die 480 may be referred to as seventh data pads 481. Data pads of the eighth semiconductor die 490 may be referred to as eighth data pads 491. The first to fourth semiconductor dies 420 to 450 may be sequentially arranged in a stepped shape such that the first to fourth data pads 421 to 451 are exposed. Similarly, the fifth to eighth semiconductor dies 460 to 490 may also be sequentially arranged in a stepped shape such that the fifth to eighth data pads 461 to 491 are exposed. For example, the second semiconductor die 430 may be disposed on the first semiconductor die 420 while being shifted in a first direction of an x-axis (a left direction along the x-axis in FIG. 6). The third semiconductor die 440 may be disposed on the second semiconductor die 430 while being shifted from the second semiconductor die 430 in the first direction. The fourth semiconductor die 450 may be disposed on the third semiconductor die 440 while being shifted from the third semiconductor die 440 in the first direction. In an embodiment, to reduce a size of the semiconductor package 400, the fifth to eighth semiconductor dies 460 to 490 may be disposed while being rotated by 180 degrees with respect to the first to fourth semiconductor dies 420 to 450, and the fifth to eighth semiconductor dies 460 to 490 may be shifted in a second direction opposite to the first direction (a right direction along the x-axis in FIG. 6). Therefore, the first to fourth data pads 421 to 451 may be exposed in the second direction, while the fifth to eighth data pads 461 to 491 may be exposed in the first direction. The fifth semiconductor die 460 may be disposed on the fourth semiconductor die 450 while being shifted from the fourth semiconductor die 450 in the first direction. The sixth semiconductor die 470 may be disposed on the fifth semiconductor die 460 while being shifted from the fifth semiconductor die 460 in the second direction. The seventh semiconductor die 480 may be disposed on the sixth semiconductor die 470 while being shifted from the sixth semiconductor die 470 in the second direction. The eighth semiconductor die 490 may be disposed on the seventh semiconductor die 480 while being shifted from the seventh semiconductor die 480 in the second direction.

The package substrate 410 may be coupled to an external apparatus through a first data bus 401 and a second data bus 402. The package substrate 410 may be coupled to the first and second data buses 401 and 402 through a package ball 411. First data DQ<1:n> may be transmitted through the first data bus 401. Second data DQ<n+1:2n> may be transmitted through the second data bus 402. The package substrate 410 may include first substrate data pads 412 and second substrate data pads 413. The first substrate data pads 412 may be coupled to the first data bus 401, and the second substrate data pads 413 may be coupled to the second data bus 402. The first substrate data pads 412 may be disposed at positions spaced apart from the first semiconductor die 420 in the second direction. The second substrate data pads 413 may be disposed at positions spaced apart from the first semiconductor die 420 in the first direction. The number of the first substrate data pads 412 may be substantially equal to the number of data transmission lines included in the first data bus 401. The number of the second substrate data pads 413 may be substantially equal to the number of data transmission lines included in the second data bus 402. The numbers of data transmission lines included in the first and second data buses 401 and 402 and the numbers of the first and second substrate data pads 412 and 413 may be equal to each other. The number of data signals included in each of the first and second data DQ<1:n> and DQ<n+1:2n> transmitted through the first and second data buses 401 and 402 may be n, and the numbers of the first and second substrate data pads 412 and 413 may each be n. Here, n may be a multiple of four or a multiple of six. The first and second substrate data pads 412 and 413 may be respectively coupled to the first and second data buses 401 and 402 through signal paths 414 and 415 formed in the package substrate 410 and the package ball 411.

The first to fourth semiconductor dies 420 to 450 may share the first data bus 401. The first data pads 421, the second data pads 431, the third data pads 441, and the fourth data pads 451 may be coupled in common to the first substrate data pads 412. The first to fourth data pads 421, 431, 441, and 451 may each include n data pads. The first data pads 421 may be coupled to the first substrate data pads 412 through first bonding wires W21. The second data pads 431 may be coupled to the first data pads 421 through second bonding wires W22. The third data pads 441 may be coupled to the second data pads 431 through third bonding wires W23. The fourth data pads 451 may be coupled to the third data pads 441 through fourth bonding wires W24. The number of the first to fourth bonding wires W21 to W24 may each be n. The fifth to eighth semiconductor dies 460 to 490 may share the second data bus 402. The fifth data pads 461, the sixth data pads 471, the seventh data pads 481, and the eighth data pads 491 may be coupled in common to the second substrate data pads 413. The fifth to eighth data pads 461, 471, 481, and 491 may each include n data pads. The fifth data pads 461 may be coupled to the second substrate data pads 413 through fifth bonding wires W25. The sixth data pads 471 may be coupled to the fifth data pads 461 through sixth bonding wires W26. The seventh data pads 481 may be coupled to the sixth data pads 471 through seventh bonding wires W27. The eighth data pads 491 may be coupled to the seventh data pads 481 through eighth bonding wires W28. The number of the fifth to eighth bonding wires W25 to W28 may each be n.

An internal circuit of the first semiconductor die 420 may be selectively coupled to the first data pads 421 based on a first enable signal EN1. An internal circuit of the second semiconductor die 430 may be selectively coupled to the second data pads 431 based on a second enable signal EN2. An internal circuit of the third semiconductor die 440 may be selectively coupled to the third data pads 441 based on a third enable signal EN3. An internal circuit of the fourth semiconductor die 450 may be selectively coupled to the fourth data pads 451 based on a fourth enable signal EN4. An internal circuit of the fifth semiconductor die 460 may be selectively coupled to the fifth data pads 461 based on a fifth enable signal EN5. An internal circuit of the sixth semiconductor die 470 may be selectively coupled to the sixth data pads 471 based on a sixth enable signal EN6. An internal circuit of the seventh semiconductor die 480 may be selectively coupled to the seventh data pads 481 based on a seventh enable signal EN7. An internal circuit of the eighth semiconductor die 490 may be selectively coupled to the eighth data pads 491 based on an eighth enable signal EN8. The external apparatus may provide a first chip selection signal CS1, a second chip selection signal CS2, a third chip selection signal CS3, and a fourth chip selection signal CS4 to the semiconductor package 400. The first and fifth semiconductor dies 420 and 460 may be accessed by the first chip selection signal CS1, and the first and fifth enable signals EN1 and EN5 may be generated based on the first chip selection signal CS1. The second and sixth semiconductor dies 430 and 470 may be accessed by the second chip selection signal CS2, and the second and sixth enable signals EN2 and EN6 may be generated based on the second chip selection signal CS2. The third and seventh semiconductor dies 440 and 480 may be accessed by the third chip selection signal CS3, and the third and seventh enable signals EN3 and EN7 may be generated based on the third chip selection signal CS3. The fourth and eighth semiconductor dies 450 and 490 may be accessed by the fourth chip selection signal CS4, and the fourth and eighth enable signals EN4 and EN8 may be generated based on the fourth chip selection signal CS4. Internal circuits of the first to fourth semiconductor dies 420 to 450 may be respectively and selectively coupled to the first to fourth data pads 421 to 451 based on the first to fourth enable signals EN1 to EN4 or the first to fourth chip selection signals CS1 to CS4. Internal circuits of the fifth to eighth semiconductor dies 460 to 490 may be respectively and selectively coupled to the fifth to eighth data pads 461 to 491 based on the fifth to eighth enable signals EN5 to EN8 or the first to fourth chip selection signals CS1 to CS4. The external apparatus may enable one of the first to fourth chip selection signals CS1 to CS4 to access one semiconductor die among the first to fourth semiconductor dies 420 to 450 together with one semiconductor die among the fifth to eighth semiconductor dies 460 to 490. For example, when the external apparatus accesses the first and fifth semiconductor dies 420 and 460, the first chip selection signal CS1 may be enabled, and the first and fifth enable signals EN1 and EN5 may be enabled based on the first chip selection signal CS1, while the second to fourth chip selection signals CS2 to CS4, the second to fourth enable signals EN2 to EN4, and the sixth to eighth enable signals EN6 to EN8 may be disabled. Accordingly, an internal circuit of the first semiconductor die 420 may be coupled to the first data pads 421, while internal circuits of the second to fourth semiconductor dies 430 to 450 may be electrically isolated from the second to fourth data pads 431 to 451. Although the first data bus 401 is coupled in common to the first to fourth data pads 421 to 451, it may be coupled to a loading of an internal circuit of the first semiconductor die 420 and might not be coupled to loadings of internal circuits of the second to fourth semiconductor dies 430 to 450. An internal circuit of the fifth semiconductor die 460 may be coupled to the fifth data pads 461, while internal circuits of the sixth to eighth semiconductor dies 470 to 490 may be electrically isolated from the sixth to eighth data pads 471 to 491. Although the second data bus 402 is coupled in common to the fifth to eighth data pads 461 to 491, it may be coupled to a loading of an internal circuit of the fifth semiconductor die 460 and might not be coupled to loadings of internal circuits of the sixth to eighth semiconductor dies 470 to 490. Because, in an embodiment, the external apparatus and/or the first and second data buses 401 and 402 may each be subjected to loading of only one semiconductor die, data transfer speeds of the first and second data buses 401 and 402 might not be reduced, and signal integrity (SI) of data transmitted through the first and second data buses 401 and 402 may be improved. In addition, in an embodiment, because the semiconductor package 400 may be coupled to more data buses, a data bandwidth between the external apparatus and the semiconductor package 400 may be increased.

The first to eighth semiconductor dies 420 to 490 may have substantially the same structure and may include components substantially identical to those of the first to fourth semiconductor dies 120 to 150 illustrated in FIG. 1. Redundant descriptions of the same components will be omitted. The first semiconductor die 420 may include the first data pads 421, a first data input/output circuit block 422, and a first switching circuit block 423. The first data input/output circuit block 422 may receive the first data DQ<1:n> during a write operation and may output the first data DQ<1:n> during a read operation. The first switching circuit block 423 may selectively couple the first data pads 421 and the first data input/output circuit block 422 based on the first enable signal EN1. The first semiconductor die 420 may further include a command address control circuit configured to generate the first enable signal EN1 based on the first chip selection signal CS1 and a command address signal. The second semiconductor die 430 may include the second data pads 431, a second data input/output circuit block 432, and a second switching circuit block 433. The second data input/output circuit block 432 may receive the first data DQ<1:n> during a write operation and may output the first data DQ<1:n> during a read operation. The second switching circuit block 433 may selectively couple the second data pads 431 and the second data input/output circuit block 432 based on the second enable signal EN2. The second semiconductor die 430 may further include a command address control circuit configured to generate the second enable signal EN2 based on the second chip selection signal CS2 and the command address signal. The third semiconductor die 440 may include the third data pads 441, a third data input/output circuit block 442, and a third switching circuit block 443. The third data input/output circuit block 442 may receive the first data DQ<1:n> during a write operation and may output the first data DQ<1:n> during a read operation. The third switching circuit block 443 may selectively couple the third data pads 441 and the third data input/output circuit block 442 based on the third enable signal EN3. The third semiconductor die 440 may further include a command address control circuit configured to generate the third enable signal EN3 based on the third chip selection signal CS3 and the command address signal. The fourth semiconductor die 450 may include the fourth data pads 451, a fourth data input/output circuit block 452, and a fourth switching circuit block 453. The fourth data input/output circuit block 452 may receive the first data DQ<1:n> during a write operation and may output the first data DQ<1:n> during a read operation. The fourth switching circuit block 453 may selectively couple the fourth data pads 451 and the fourth data input/output circuit block 452 based on the fourth enable signal EN4. The fourth semiconductor die 450 may further include a command address control circuit configured to generate the fourth enable signal EN4 based on the fourth chip selection signal CS4 and the command address signal.

The fifth semiconductor die 460 may include the fifth data pads 461, a fifth data input/output circuit block 462, and a fifth switching circuit block 463. The fifth data input/output circuit block 462 may receive the second data DQ<n+1:2n> during a write operation and may output the second data DQ<n+1:2n> during a read operation. The fifth switching circuit block 463 may selectively couple the fifth data pads 461 and the fifth data input/output circuit block 462 based on the fifth enable signal EN5. The fifth semiconductor die 460 may further include a command address control circuit configured to generate the fifth enable signal EN5 based on the first chip selection signal CS1 and the command address signal. The sixth semiconductor die 470 may include the sixth data pads 471, a sixth data input/output circuit block 472, and a sixth switching circuit block 473. The sixth data input/output circuit block 472 may receive the second data DQ<n+1:2n> during a write operation and may output the second data DQ<n+1:2n> during a read operation. The sixth switching circuit block 473 may selectively couple the sixth data pads 471 and the sixth data input/output circuit block 472 based on the sixth enable signal EN6. The sixth semiconductor die 470 may further include a command address control circuit configured to generate the sixth enable signal EN6 based on the second chip selection signal CS2 and the command address signal. The seventh semiconductor die 480 may include the seventh data pads 481, a seventh data input/output circuit block 482, and a seventh switching circuit block 483. The seventh data input/output circuit block 482 may receive the second data DQ<n+1:2n> during a write operation and may output the second data DQ<n+1:2n> during a read operation. The seventh switching circuit block 483 may selectively couple the seventh data pads 481 and the seventh data input/output circuit block 482 based on the seventh enable signal EN7. The seventh semiconductor die 480 may further include a command address control circuit configured to generate the seventh enable signal EN7 based on the third chip selection signal CS3 and the command address signal. The eighth semiconductor die 490 may include the eighth data pads 491, an eighth data input/output circuit block 492, and an eighth switching circuit block 493. The eighth data input/output circuit block 492 may receive the second data DQ<n+1:2n> during a write operation and may output the second data DQ<n+1:2n> during a read operation. The eighth switching circuit block 493 may selectively couple the eighth data pads 491 and the eighth data input/output circuit block 492 based on the eighth enable signal EN8. The eighth semiconductor die 490 may further include a command address control circuit configured to generate the eighth enable signal EN8 based on the fourth chip selection signal CS4 and the command address signal.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A semiconductor package comprising:
a package substrate having substrate data pads coupled to a data bus through which data is transmitted;
a first semiconductor die disposed on the package substrate; and
a second semiconductor die disposed on the first semiconductor die,
wherein the first semiconductor die comprises:
first data pads coupled to the substrate data pads;
a first data input/output (input and output) circuit block configured to generate first internal data based on the data during a write operation and configured to generate the data based on the first internal data during a read operation; and
a first switching circuit block configured to selectively couple the first data pads and the first data input/output circuit block based on a first chip selection signal, and
wherein the second semiconductor die comprises:
second data pads coupled to the substrate data pads;
a second data input/output circuit block configured to generate second internal data based on the data during a write operation and configured to generate the data based on the second internal data during a read operation; and
a second switching circuit block configured to selectively couple the second data pads and the second data input/output circuit block based on a second chip selection signal.

2. The semiconductor package of claim 1, wherein the package substrate is coupled to an external apparatus through the data bus.

3. The semiconductor package of claim 1, wherein the first data pads are respectively coupled to the substrate data pads through first bonding wires, and the second data pads are respectively coupled to the first data pads through second bonding wires.

4. The semiconductor package of claim 1, wherein the first semiconductor die further comprises a command address control circuit configured to generate a first enable signal based on a command address signal and the first chip selection signal, and the first switching circuit block is configured to electrically couple the first data pads and the first data input/output circuit block based on the first enable signal.

5. The semiconductor package of claim 4, wherein the command address control circuit comprises:
a command decoding circuit configured to decode the command address signal to generate a write signal and a read signal when the first chip selection signal is enabled;
a pulse generation circuit configured to generate a write enable signal from the write signal based on write latency information and burst length information and configured to generate a read enable signal from the read signal based on read latency information and the burst length information; and
an enable signal generation circuit configured to enable the first enable signal when any one of the write enable signal and the read enable signal is enabled.

6. The semiconductor package of claim 1, wherein the second semiconductor die further comprises a command address control circuit configured to generate a second enable signal based on a command address signal and the second chip selection signal, and the second switching circuit block is configured to electrically couple the second data pads and the second data input/output circuit block based on the second enable signal.

7. The semiconductor package of claim 6, wherein the command address control circuit comprises:
a command decoding circuit configured to decode the command address signal to generate a write signal and a read signal when the second chip selection signal is enabled;
a pulse generation circuit configured to generate a write enable signal from the write signal based on write latency information and burst length information and configured to generate a read enable signal from the read signal based on read latency information and the burst length information; and
an enable signal generation circuit configured to enable the second enable signal when any one of the write enable signal and the read enable signal is enabled.

8. A semiconductor package comprising:
a package substrate including substrate data pads coupled to a data bus through which data is transmitted;
a first semiconductor die disposed on the package substrate; and
a second semiconductor die disposed on the first semiconductor die,
wherein first data pads of the first semiconductor die and second data pads of the second semiconductor die are coupled in common with the substrate data pads, and
wherein the first data pads are selectively coupled to a data input/output (input and output) circuit block of the first semiconductor die based on a first enable signal, and the second data pads are selectively coupled to a data input/output circuit block of the second semiconductor die based on a second enable signal.

9. The semiconductor package of claim 8, wherein during a write operation of the first semiconductor die, the first enable signal is enabled before the data is received through the first data pads and is disabled after the reception of the data through the first data pads is completed, and during a read operation of the first semiconductor die, the first enable signal is enabled before the data is output from the data input/output circuit block and is disabled after the output of the data from the data input/output circuit block is completed.

10. The semiconductor package of claim 8, wherein the first semiconductor die further comprises a command address control circuit configured to generate the first enable signal based on a first chip selection signal and a command address signal.

11. The semiconductor package of claim 10, wherein the command address control circuit comprises:
a command decoding circuit configured to decode the command address signal to generate a write signal and a read signal when the first chip selection signal is enabled;
a pulse generation circuit configured to generate a write enable signal from the write signal based on write latency information and burst length information and configured to generate a read enable signal from the read signal based on read latency information and the burst length information; and
an enable signal generation circuit configured to enable the first enable signal when any one of the write enable signal and the read enable signal is enabled.

12. The semiconductor package of claim 8, wherein during a write operation of the second semiconductor die, the second enable signal is enabled before the data is transmitted through the second data pads and is disabled after the transmission of the data through the second data pads is completed, and during a read operation of the second semiconductor die, the second enable signal is enabled before the data is output from the data input/output circuit block and is disabled after the output of the data from the data input/output circuit block is completed.

13. The semiconductor package of claim 8, wherein the second semiconductor die further comprises a command address control circuit configured to generate the second enable signal based on a second chip selection signal and a command address signal.

14. The semiconductor package of claim 13, wherein the command address control circuit comprises:
a command decoding circuit configured to decode the command address signal to generate a write signal and a read signal when the second chip selection signal is enabled;
a pulse generation circuit configured to generate a write enable signal from the write signal based on write latency information and burst length information and configured to generate a read enable signal from the read signal based on read latency information and the burst length information; and
an enable signal generation circuit configured to enable the second enable signal when any one of the write enable signal and the read enable signal is enabled.

15. A semiconductor package comprising:
a package substrate including first substrate data pads coupled to a first data bus and second substrate data pads coupled to a second data bus;
a first semiconductor die disposed on the package substrate;
a second semiconductor die disposed on the first semiconductor die;
a third semiconductor die disposed on the second semiconductor die; and
a fourth semiconductor die disposed on the third semiconductor die,
wherein first data pads of the first semiconductor die and second data pads of the second semiconductor die are coupled in common with the first substrate data pads, and third data pads of the third semiconductor die and fourth data pads of the fourth semiconductor die are coupled in common with the second substrate data pads,
wherein when a first chip selection signal is enabled, a data input/output (input and output) circuit block of the first semiconductor die is electrically coupled to the first data pads and a data input/output circuit block of the third semiconductor die is electrically coupled to the third data pads, and
wherein when a second chip selection signal is enabled, a data input/output circuit block of the second semiconductor die is electrically coupled to the second data pads and a data input/output circuit block of the fourth semiconductor die is electrically coupled to the fourth data pads.

16. The semiconductor package of claim 15, wherein the first data pads are coupled to the first substrate data pads through first bonding wires, the second data pads are coupled to the first data pads through second bonding wires, the third data pads are coupled to the second substrate data pads through third bonding wires, and the fourth data pads are coupled to the third data pads through fourth bonding wires.

17. The semiconductor package of claim 15, wherein the first semiconductor die further comprises:
a first command address control circuit configured to generate a first enable signal based on the first chip selection signal and a command address signal; and
a first switching circuit block configured to electrically couple a data input/output circuit block of the first semiconductor die to the first data pads based on the first enable signal.

18. The semiconductor package of claim 17, wherein the second semiconductor die further comprises:
a second command address control circuit configured to generate a second enable signal based on the second chip selection signal and the command address signal; and
a second switching circuit block configured to electrically couple a data input/output circuit block of the second semiconductor die to the second data pads based on the second enable signal.

19. The semiconductor package of claim 17, wherein the third semiconductor die further comprises:
a third command address control circuit configured to generate a third enable signal based on the first chip selection signal and the command address signal; and
a third switching circuit block configured to electrically couple a data input/output circuit block of the third semiconductor die to the third data pads based on the third enable signal.

20. The semiconductor package of claim 17, wherein the fourth semiconductor die further comprises:
a fourth command address control circuit configured to generate a fourth enable signal based on the second chip selection signal and the command address signal; and
a fourth switching circuit block configured to electrically couple a data input/output circuit block of the fourth semiconductor die to the fourth data pads based on the fourth enable signal.
